(19) United States
(12) Patent Application Publication
(10) Pub. No.: US 2018/0329304 A1
(43) Pub. Date: Nov. 15, 2018

(54) SUBSTRATE BAKING APPARATUS AND BAKING OPERATION MEHOD THEREOF

(71) Applicants: HKC CORPORATION LIMITED, SHENZHEN CITY, GUANGDONG (CN); CHONGQING HKC OPTOELLECTRONICS TECHNOLOGY CORPORATION LIMITED, CHONGQING (CN)

(72) Inventor: CHUN-CHIN HUANG, CHONGQING (CN)

(21) Appl. No.: 15/540,846

(22) PCT Filed: Feb. 26, 2017
(86) PCT No.: PCT/CN2017/074911

§ 371 Date: Jun. 29, 2017

(30) Foreign Application Priority Data
Dec. 19, 2016 (CN) 201611179255.4

(51) Int. Cl. G03F 7/40; H01L 21/67; G03F 7/38

(52) U.S. Cl. CPC G03F 7/40; G03F 7/38; H01L 21/67109

(57) ABSTRACT

This application provides a substrate baking apparatus and a baking operation method. The apparatus includes: a ring-shaped bearer body, used to cover a substrate; a cover plate, disposed on the ring-shaped bearer body, which, together with the cover plate, defines a sealed chamber, where a surface of the substrate is located inside the sealed chamber; an air intake unit and an exhaust discharge unit, respectively disposed on an intake end and a discharge end of the sealed chamber; and an exhaust regulation air-extraction system, disposed on an upper part of the cover plate, communicated with the sealed chamber, and used to regulate and discharge evaporated gases of a great number of volatiles of the substrate.

### BACKGROUND

### Technical Field

This application relates to a design for controlling stability flowage of an air flow, and in particular, to a substrate baking apparatus and a baking operation method thereof.

### Related Art

A liquid crystal display panel is usually constituted by a color filter (CF) substrate, a thin film transistor array substrate (TFT array substrate), and a liquid crystal layer disposed between the two substrates. A working principle of the liquid crystal display panel is applying a drive voltage on the two glass substrates to control rotation of liquid crystal molecules of the liquid crystal layer, so as to refract light rays of a backlight module to generate an image. In a preliminary-stage process of a thin film transistor-liquid crystal display (TFT-LCD) and a color filter, after coating a photo-resist used for a product in a photo process, a content of a solvent of the photo-resist on a glass surface is relatively high, so that the product needs to be put into a heating oven for a pre-bake action before exposure. In a pre-bake heating process, a great number of organic gas volatiles of the solvent and the photo-resist are generated on the glass surface, so that an air flow direction system needs to be designed for the heating oven, so as to reduce subsequent effects of the volatiles on the process.

Existing drying manners are generally classified into two types. A first manner is blowing external air into a drying apparatus by using an air blower, and heating inhaled air, so as to continuously increase hot air to dry a to-be-dried object accommodated in the drying apparatus. A second manner is vacuum drying. However, there are three disadvantages in drying in the first manner. A first disadvantage is that if the to-be-dried object is taken out from an interior of the drying apparatus, an internal temperature abruptly decreases because a door is open and the to-be-dried object is in contact with external air, which, further, affects drying efficiency of subsequent other to-be-dried objects. A second disadvantage is that poor design of internal air exhaust and intake of the drying apparatus causes air flow turbulence. As a result, gases volatilized from volatile liquids cannot be completely exhausted successfully. In addition, the air blower is not designed to supply air in a single direction, which, as a result, increases a possibility that when being in contact with a running machine such as a motor, volatile gases cause an electric arc or a spark, and further generate an explosion or fire. A third disadvantage is that some volatile gases that cannot be exhausted successfully may corrode electrodes of a machine such as a motor, resulting in poor contact. The second drying manner also has disadvantages. On the one hand, to establish a vacuum environment, a vacuum pumping device is required. On the other hand, a working gas, such as nitrogen, needs to be continuously supplied, to perform a drying operation. To satisfy the foregoing two conditions, more precise electronic control devices need to be disposed. As a result, costs of use of the vacuum pumping manner are excessively high.

### SUMMARY

To resolve the foregoing technical problems, this application is directed to providing design of controlling stable flowing of an air flow, and in particular, to a substrate baking apparatus and a baking operation method thereof. Regulation and control may be performed for different volatile materials, and such a device is applied to pre-drying oven processes of different volatile materials.

To achieve the objective of this application and resolve technical problems of this application, the following technical solutions are used. A substrate baking apparatus provided in this application includes: a ring-shaped bearer body, used to cover a substrate; a cover plate, disposed on the ring-shaped bearer body, which, together with the cover plate, defines a sealed chamber, where a surface of the substrate is located inside the sealed chamber; an air intake unit and an exhaust discharge unit, disposed on an intake end and a discharge end of the sealed chamber, respectively; and an exhaust regulation air-extraction system, disposed on an upper part of the cover plate, communicated with the sealed chamber, and used to regulate and discharge evaporated gases of a great number of volatiles of the substrate.

To further achieve the objective of this application and resolve technical problems of this application, the following technical measures may be taken.

A substrate baking operation method is provided, including: providing the substrate baking apparatus; heating, based on a heating unit of the apparatus, substrates to generate volatile gases on the substrates; and discharging the volatile gases by using the air intake unit, the exhaust discharge unit, and the exhaust regulation air-extraction system.

In an embodiment of this application, the substrate baking apparatus further includes: an exhaust regulation valve, mounted around an upper part of the sealed chamber and used to regulate the volatile a gas around the sealed chamber.

In an embodiment of this application, the exhaust regulation air-extraction system further includes: an exhaust pipe unit, which guides volatile gases on substrates to an exhaust pipeline to be discharged.

In an embodiment of this application, the air intake unit is a dry-and-clean air intake unit.

In an embodiment of this application, the exhaust discharge unit is an exhaust motor.

In an embodiment of this application, the exhaust regulation air-extraction system has a plurality of holes communicated with the sealed chamber.

In an embodiment of this application, the substrate baking apparatus further includes: a control panel unit, used to perform heating and discharging operations of the apparatus; and a heating unit, used to heat the substrate and perform a volatilization operation on the substrate, where the substrate may be a color filter or at least one wafer.

In an embodiment of this application, in the method, the step of discharging the volatile gases by using the air intake unit, the exhaust discharge unit, and the exhaust regulation air-extraction system includes: driving the volatile gases on a surface of the substrate by using the air intake unit; regulating a volatile gas around the sealed chamber by using an exhaust regulation valve unit; guiding, by means of the exhaust pipe unit, volatile gases on substrates to an exhaust pipeline to be discharged; and extracting, by using the exhaust discharge unit, the volatile gases on the substrates out of the apparatus.

In an embodiment of this application, in the method, the exhaust discharge unit is an exhaust motor.

Beneficial effects of this application are that: for different volatile materials, not only regulation and control may be performed, but also stable flowing of air flows may be controlled, and such a device is applied to pre-drying oven processes of different volatile materials.

### BRIEF DESCRIPTION OF THE DRAWINGS

FIG. 1a is a schematic diagram of an exemplary substrate baking apparatus;

FIG. 1b is a schematic diagram of an exemplary substrate baking apparatus;

FIG. 2a is a schematic diagram of a substrate baking apparatus according to this application; and

FIG. 2b is a schematic diagram of an exhaust regulation valve according to this application.

### DETAILED DESCRIPTION

The following embodiments are described with reference to the accompanying drawings, and are examples of particular embodiments that may be implemented in this application. Directional terms mentioned in this application, for example, “above”, “below”, “front”, “back”, “left”, “right”, “inside”, “outside”, and “side surface”, are merely directions for referring to the accompanying drawings. Therefore, the used directional terms are intended for description and understanding other than limiting this application.

The accompanying drawings and the descriptions are considered to be essentially illustrative instead of being limitative. In the figures, units having similar structures are represented by using a same reference sign. In addition, for understanding and ease of description, the size and thickness of each component shown in the accompany drawings are randomly illustrated. No limitation is imposed in this application.

In the accompany drawings, for the purpose of clear description, the thicknesses of a layer, a film, a panel, an area, and the like are exaggerated. In the accompanying drawings, for understanding and ease of description, thicknesses of some layers and areas are exaggerated. It will be understood that, for example, when a component of a layer, a film, an area, or a substrate is referred to as “being” “on” another component, the component may be directly on the another component, or there is an intermediate component.

In addition, in the specification, unless being explicitly described as the contrary, the word “include” may be understood to imply the inclusion of stated components but not the exclusion of any other components. Moreover, in the specification, “on” refers to being above or below a target component, but not refers to being on top in a direction of gravity.

To further describe technical means adopted in this application for achieving the present invention objective and effects of this application, the following describes specific implementations, structures, features, and effects of a substrate baking apparatus and a baking operation method thereof provided according to this application in detail with reference to the accompany drawings and preferred embodiments.

A hot wind oven is mainly used for pre-bake. In a heating process, a great number of organic gas volatiles of solvent and a photo-resist are generated on a glass surface. In the hot wind oven, external air is inhaled into the oven, the air is heated, and the heated air bakes a glass substrate. In addition, the hot wind oven is connected to an external heat exchanger by using an external pipeline, so as to properly discharge hot air including an ink volatile gas, so that the ink that is volatilized into the gas is not attached to or accumulated on an inner oven body.

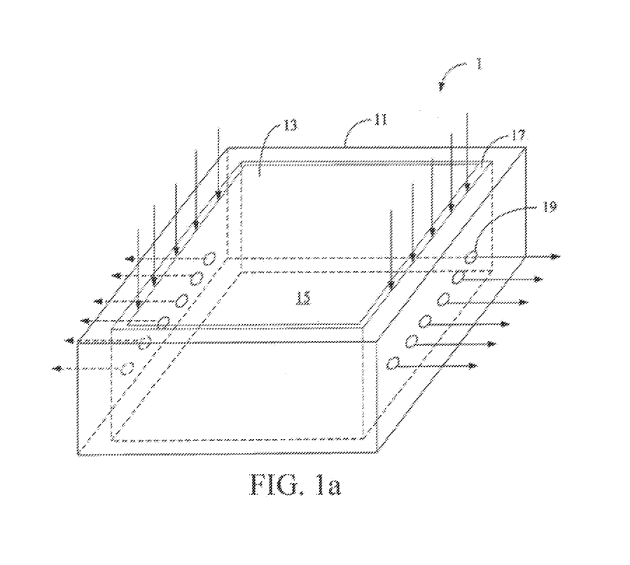

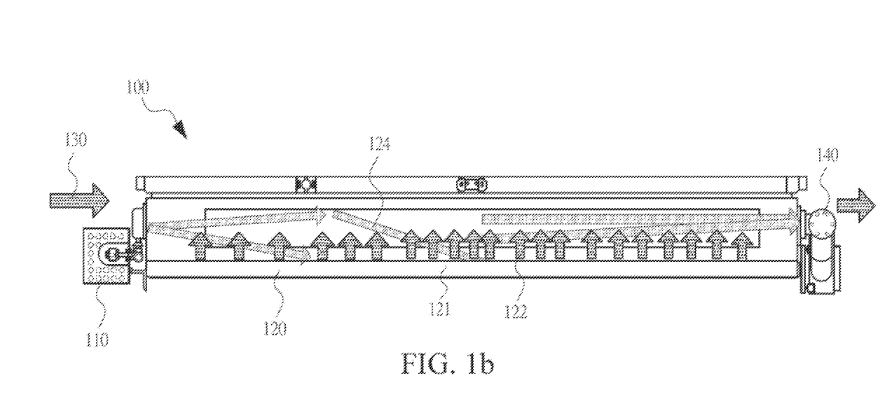

FIG. 1a is a schematic diagram of an exemplary substrate baking apparatus. In current design, air is extracted out by using exhaust holes on two sides of an oven, as shown in FIG. 1a. The substrate baking apparatus 1 includes an accommodation body 11 and a cover plate 13. The accommodation body 11 and the cover plate 13 define a chamber 15. There is a gap 17 between the accommodation body 11 and the cover plate 13, and the gap 17 is used to inhale cold air. A plurality of exhaust holes 19 are provided on a side wall of the accommodation body 11, and are used to discharge volatile gas mixed with the cold air. Because the cover plate 13 on the chamber 15 is not designed to be sealed or heat-insulating, in the gap 17 between the cover plate 13 and the chamber 15, external cold air affected by negative pressure generated due to an exhaust force and causes a thermal shock on photo-resist volatile gases having relatively high temperatures. As a result, undesirable residues are generated and condensed at a particular position of the substrate. In a subsequent process, the undesirable residues of the photo-resist are easily dropped onto a glass surface of the substrate, and affect a subsequent operation of the apparatus. In addition, a common defect is also generated on an exposure apparatus, the apparatus needs to be shut down for cleaning a mask, and a proportion that the apparatus needs to be shut down for regular maintenance and pre-maintenance (PM) is relatively high. Consequently, productivity is severely affected.

Therefore, to avoid a thermal shock caused by cold air inhaled into the chamber due to the negative pressure, which further makes photo-resist volatiles drop onto the glass surface, and affects manufacturing quality, a technology capable of isolating external cold air and capable of exhausting organic volatile gases from an interior of the chamber is urgently needed in the industry.

FIG. 1b is a schematic diagram of an exemplary substrate 121 baking apparatus 100. Referring to FIG. 1b, the substrate 121 baking apparatus 100 includes a control panel unit 110, used to perform heating and discharging operations of the apparatus 100; a heating unit 120, used to heat a plurality of substrates 121 and perform volatilization operations on the substrates 121; a dry-and-clean air intake unit 130, used to drive volatile gases 122 and 124 on the apparatus 100; and an exhaust discharge unit 140, used to extract the volatile gases 122 and 124 of the substrates 121 out of the apparatus 100.

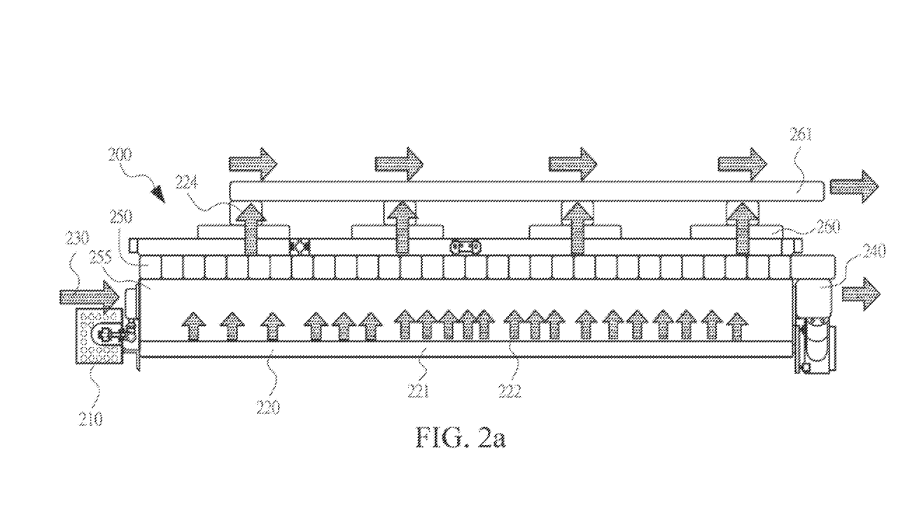

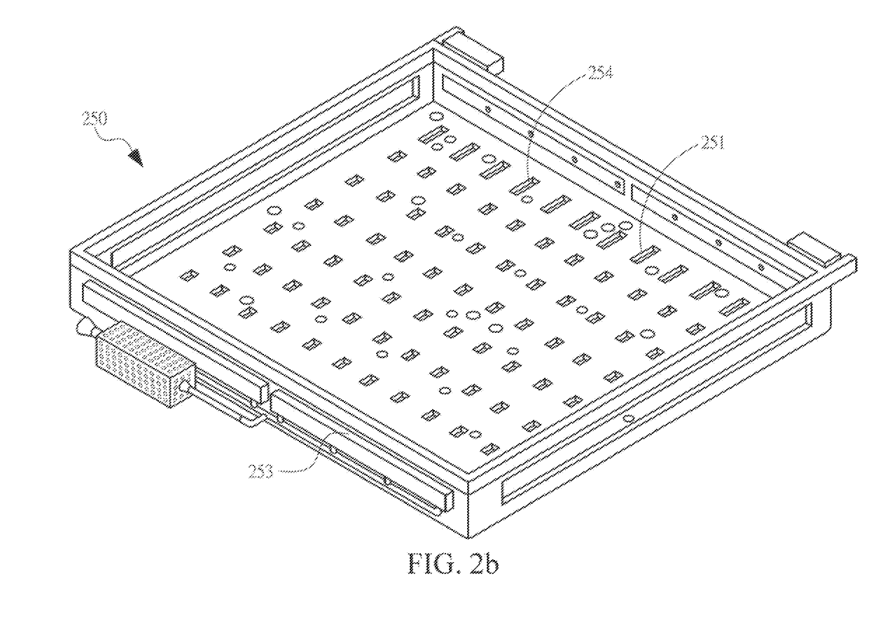

FIG. 2a is a schematic diagram of a substrate 221 baking apparatus 200 according to this application and FIG. 2b is a schematic diagram of an exhaust regulation valve 253 according to this application. Referring to FIG. 2a and FIG. 2b, in an embodiment of this application, the substrate 221 baking apparatus 200 according to this application includes: a ring-shaped bearer body 250, a cover plate 251, an air intake unit 230, an exhaust discharge unit 240, an exhaust regulation air-extraction system 260, a control panel unit 210, a heating unit 220, and an exhaust regulation valve 253. The ring-shaped bearer body 250 is used to cover a substrate 221. The cover plate 251 is disposed on the ring-shaped bearer body 250, which, together with the cover plate 251, defines a sealed chamber 255, where a surface of the substrate 220 is located inside the sealed chamber 255. The air intake unit 230 and the exhaust discharge unit 240 are disposed on an intake end 230 and a discharge end 240 of the sealed chamber 255, respectively. The exhaust regulation air-extraction system 260 is disposed on an upper part of the cover plate 251, communicated with the sealed chamber 255, and used to regulate and discharge evaporated gases 222 and 224 of a great number of volatiles of the substrate 221. The control panel unit 210 is used to perform heating and discharging operations of the apparatus 200. The heating unit 220 is used to heat the substrate 221 and perform a volatilization operation on the substrate 221. The exhaust regulation valve 253 is mounted around an upper part of the sealed chamber 255 and used to regulate the volatile gas 222 around the sealed chamber 255.

In an embodiment, the exhaust regulation air-extraction system 260 further includes an exhaust pipe unit 261. The exhaust pipe unit 261 is used to guide the volatile gases 222 and 224 of substrates 221 to an exhaust pipeline to be discharged.

In an embodiment, the substrate 221 may be a color filter substrate, an active switch array substrate, a silicon chip, or at least one wafer.

In an embodiment, the air intake unit 230 is a dry-and-clean air intake unit.

In an embodiment, the exhaust discharge unit 240 is an exhaust motor.

In an embodiment, the exhaust pipe unit 261 is an exhaust device.

In an embodiment, the exhaust regulation air-extraction system 260 has a plurality of holes 254 communicated with the sealed chamber 255.

Referring to FIG. 2a and FIG. 2b, in an embodiment of this application, a substrate 221 baking operation method according to this application includes: providing the substrate 221 baking apparatus 200; heating, based on the heating unit 220, the substrates 221 to generate volatile gases 222 and 224 of the substrates 221; and discharging the volatile gases 222 and 224 by using the air intake unit 230, the exhaust discharge unit 240, and the exhaust regulation air-extraction system 260.

In an embodiment, in the method, the step of discharging the volatile gases 222 and 224 by using the air intake unit 230, the exhaust discharge unit 240, and the exhaust regulation air-extraction system 260 includes: driving the volatile gases 222 and 224 on a surface of the substrate 221 by using the air intake unit 230; regulating the volatile gas 222 around the sealed chamber 255 by using the exhaust regulation valve unit 253; guiding, by means of the exhaust pipe unit 261, the volatile gas 222 of the substrates 221 to an exhaust pipeline to discharge it; and extracting, by using the exhaust discharge unit 240, the volatile gases 222 and 224 of the substrates 221 out of the apparatus 200.

In an embodiment, the substrate 221 baking apparatus 200 includes: a ring-shaped bearer body 250, a cover plate 251, an air intake unit 230, an exhaust discharge unit 240, an exhaust regulation air-extraction system 260, a control panel unit 210, a heating unit 220, and an exhaust regulation valve 253. The ring-shaped bearer body 250 is used to cover a substrate 221. The cover plate 251 is disposed on the ring-shaped bearer body 250, which, together with the cover plate 251, defines a sealed chamber 255, where a surface of the substrate 220 is located inside the sealed chamber 255. The air intake unit 230 and the exhaust discharge unit 240 are disposed on an intake end 230 and a discharge end 240 of the sealed chamber 255, respectively. The exhaust regulation air-extraction system 260 is disposed on an upper part of the cover plate 251, communicated with the sealed chamber 255, and used to regulate and discharge evaporated gases 222 and 224 of a great number of volatiles of the substrate 221. The control panel unit 210 is used to perform heating and discharging operations of the apparatus 200. The heating unit 220 is used to heat the substrate 221 and perform a volatilization operation on the substrate 221. The exhaust regulation valve 253 is mounted around an upper part of the sealed chamber 255 and used to regulate the volatile gases 222 and 224 around the sealed chamber 255.

In an embodiment, the exhaust regulation air-extraction system 260 further includes an exhaust pipe unit 261. The exhaust pipe unit 261 is used to guide the volatile gases 222 and 224 of substrates 221 to an exhaust pipeline to be discharged.

In an embodiment, the substrate 221 may be a color filter, an active switch array substrate, a silicon chip, or at least one wafer.

In an embodiment, the air intake unit 230 is a dry-and-clean air intake unit.

In an embodiment, the exhaust discharge unit 240 is an exhaust motor.

In an embodiment, the exhaust pipe unit 261 is an exhaust device.

In an embodiment, the exhaust regulation air-extraction system 260 has a plurality of holes 254, which are communicated with the sealed chamber 255.

Beneficial effects of this application are that: for different volatile materials, not only regulation and control may be performed, but also stable flowing of air flows may be controlled, and such a device is applied to pre-drying oven processes of different volatile materials.

Terms “in some embodiments” and “in various embodiments” are repeatedly used. These terms usually do not refer to same embodiments; but may also refer to same embodiments. Terms “include”, “have”, and “comprise” are synonyms unless other meanings are implied in the contexts.

The foregoing descriptions are merely preferred embodiments of this application, but are not intended to limit this application in any form. Although this application has been described by using the preferred embodiments, the descriptions are not intended to limit this application. Modifications, equivalent variations, or equivalent embodiments can be made by persons skilled in the art by using the foregoing disclosed technical content without departing from the scope of the technical solutions of this application. Any simple modification, equivalent variations, or equivalent embodiments made without departing from the content of the technical solutions of this application and according to the technical essence of this application shall fall within the scope of the technical solutions of this application.

What is claimed is:

1. A substrate baking apparatus, comprising:
a ring-shaped bearer body, configured to cover a substrate;
a cover plate, disposed on the ring-shaped bearer body, wherein the cover plate and the ring-shaped bearer body define a sealed chamber, and a surface of the substrate is located inside the sealed chamber;
an air intake unit and an exhaust discharge unit, disposed on an intake end and a discharge end of the sealed chamber respectively; and
an exhaust regulation air-extraction system, disposed on an upper part of the cover plate, communicated with the sealed chamber, and configured to regulate and discharge evaporated gases of a great number of volatiles of the substrate.

2. The substrate baking apparatus according to claim 1, further comprising:
an exhaust regulation valve, mounted around an upper part of the sealed chamber and configured to regulate a volatile gas around the sealed chamber.

3. The substrate baking apparatus according to claim 1, wherein the exhaust regulation air-extraction system further comprises:
an exhaust pipe unit guiding volatile gases on substrates to an exhaust pipeline to be discharged.

4. The substrate baking apparatus according to claim 1, wherein the air intake unit is a dry-and-clean air intake unit.

5. The substrate baking apparatus according to claim 1, wherein the exhaust discharge unit is an exhaust motor.

6. The substrate baking apparatus according to claim 1, wherein the exhaust regulation air-extraction system has a plurality of holes communicated with the sealed chamber.

7. The substrate baking apparatus according to claim 1, further comprising:
a control panel unit, used to perform heating and discharging operations of the apparatus; and
a heating unit, used to heat the substrate and perform a volatilization operation on the substrate.

8. A substrate baking operation method, applied to a substrate baking apparatus, wherein the apparatus comprises:
a ring-shaped bearer body, used to cover a substrate;
a cover plate, disposed on the ring-shaped bearer body, wherein the cover plate and the ring-shaped bearer body define a sealed chamber, and a surface of the substrate is located inside the sealed chamber;
an air intake unit and an exhaust discharge unit, disposed on an intake end and a discharge end of the sealed chamber, respectively;
an exhaust regulation air-extraction system, disposed on an upper part of the cover plate, communicated with the sealed chamber, and used to regulate and discharge evaporated gases of a great number of volatiles of the substrate;
a control panel unit, used to perform heating and discharging operations of the apparatus; and
a heating unit, used to heat the substrate and perform a volatilization operation on the substrate, and the method comprises: heating, based on the heating unit of the apparatus, substrates to generate volatile gases on the substrates; and
discharging the volatile gases by using the air intake unit, the exhaust discharge unit, and the exhaust regulation air-extraction system.

9. The substrate baking operation method according to claim 8, wherein the step of discharging the volatile gases by using the air intake unit, the exhaust discharge unit, and the exhaust regulation air-extraction system comprises:
driving the volatile gases on a surface of the substrate by using the air intake unit;
regulating a volatile gas around the sealed chamber by using an exhaust regulation valve unit;
guiding, by means of an exhaust pipe unit, the volatile gases on the substrates to a pipeline to be discharged; and
extracting, by using the exhaust discharge unit, the volatile gases on the substrates out of the apparatus.

10. The substrate baking operation method according to claim 8, further comprising:
an exhaust regulation valve, mounted around an upper part of the sealed chamber, and used to regulate the volatile gas around the sealed chamber.

11. The substrate baking operation method according to claim 8, wherein the exhaust regulation air-extraction system further comprises: an exhaust pipe unit, which guides volatile gases on substrates to an exhaust pipeline to be discharged.

12. The substrate baking operation method according to claim 8, wherein the air intake unit is a dry-and-clean air intake unit.

13. The substrate baking operation method according to claim 8, wherein the exhaust discharge unit is an exhaust motor.

14. The substrate baking operation method according to claim 8, wherein the exhaust regulation air-extraction system has a plurality of holes communicated with the sealed chamber.

15. A substrate baking apparatus, comprising:
a ring-shaped bearer body, used to cover a substrate;
a cover plate, disposed on the ring-shaped bearer body, wherein the cover plate and the ring-shaped bearer body define a sealed chamber, and a surface of the substrate is located inside the sealed chamber;
an air intake unit and an exhaust discharge unit, disposed on an intake end and a discharge end of the sealed chamber, respectively;
an exhaust regulation air-extraction system, disposed on an upper part of the cover plate, communicated with the sealed chamber, and used to regulate and discharge evaporated gases of a great number of volatiles of the substrate;
an exhaust regulation valve, mounted around an upper part of the sealed chamber and used to regulate a volatile gas around the sealed chamber;
a control panel unit, used to perform heating and discharging operations of the apparatus; and
a heating unit, used to heat the substrate and perform a volatilization operation on the substrate, wherein
the exhaust regulation air-extraction system further comprises: an exhaust pipe unit,—guiding volatile gases on substrates to an exhaust pipeline to be discharged;
the air intake unit is a dry-and-clean air intake unit;
the exhaust discharge unit is an exhaust motor; and
the exhaust regulation air-extraction system has a plurality of holes communicated with the sealed chamber, wherein the substrate is a color filter or at least one wafer.
